(19) United States
(12) Patent Application Publication
(10) Pub. No.: US 2015/0083187 A1
(43) Pub. Date: Mar. 26, 2015

(54) SOLAR CELL MODULE AND SOLAR CELL MODULE MANUFACTURING METHOD

(71) Applicant: Sanyo Electric Co., Ltd., Osaka (JP)

(72) Inventors: Haruhisa HASHIMOTO, Osaka (JP); Atsushi SAITA, Hyogo (JP)

(21) Appl. No.: 14/560,220

(22) Filed: Dec. 4, 2014

Related U.S. Application Data
(63) Continuation of application No. PCT/JP2012/066772, filed on Jun. 29, 2012.

(51) Int. Cl. H01L 31/0224

(52) U.S. Cl. CPC H01L 31/022433
USPC 136/244

(57) ABSTRACT

This solar cell module is provided with a plurality of solar cells, and connecting members that connect the solar cells to each other with bonding layers therebetween. At an edge portion of each of the connecting members, said edge portion being in the longitudinal direction of the connecting member, the solar cell module has a bonding portion wherein the length of contact between each of the bonding layers and each of the connecting members is longer than the length of such contact at the center portion of each of the solar cells.

### CROSS-REFERENCE TO RELATED APPLICATION

The present application is a continuation under 35 U.S.C §120 of PCT/JP2012/066772, filed on Jun. 29, 2012, which is incorporated herein by reference.

### TECHNICAL FIELD

The present invention relates to a solar cell module and a solar cell module manufacturing method.

### BACKGROUND ART

A solar cell module 100 has, as shown in FIG. 7, a structure in which collecting electrodes 12 provided in a plurality of solar cells 10 are connected to each other by means of connecting members 14. The connecting members 14 are conductively adhered to the collecting electrodes 12 by means of a conductive adhesive film in which conductive particles are dispersed (see Patent Document 1).

### CITATION LIST

### Patent Document

Patent Document 1: JP 2011-108985 A

If the adhesive force between the solar cell 10 and the connecting member 14 decreases, there is a risk that the connecting member 14 peels off. Meanwhile, if too much adhesive is used to enhance the adhesive force, the adhesive protrudes from the connecting member 14, and the protruding adhesive shades the solar cell 10, which may cause degradation of the conversion efficiency.

### SUMMARY

According to one embodiment of the present invention, there is provided a solar cell module having a plurality of solar cells, and a connecting member which connects between the plurality of solar cells via an adhesive layer, and the solar cell module has an adhesion portion having a contact length between the adhesive layer and the connecting member, the contact length being longer at an edge portion than at a central portion of the solar cell along the longitudinal direction of the connecting member.

According to another embodiment of the present invention, there is provided a method of manufacturing a solar cell module including a first step of applying an adhesive onto a plurality of solar cells, the adhesive becoming an adhesive layer, and a second step of connecting between the plurality of solar cells by means of a connecting member via the adhesive layer, and, in this method, there is provided an adhesion portion having a contact length between the adhesive layer and the connecting member, the contact length being longer at an edge portion than at a central portion of the solar cell along the longitudinal direction of the connecting member.

### ADVANTAGEOUS EFFECT OF INVENTION

With the present invention, it is possible to strengthen contact between the solar cell and the connecting member in the solar cell module, and reduce shading loss.

### BRIEF DESCRIPTION OF THE DRAWINGS

FIG. 1 shows a plan view illustrating a solar cell module in an embodiment of the present invention.

FIG. 2 shows a cross-sectional view illustrating the solar cell module in the embodiment of the present invention.

FIG. 3 shows a cross-sectional view illustrating the solar cell module in the embodiment of the present invention.

FIG. 4 shows a cross-sectional view illustrating a joint member having a surface on which uneven shape is provided in the embodiment of the present invention.

FIG. 5 shows a plan view illustrating an adhesive layer in the embodiment of the present invention.

FIG. 6 shows a cross-sectional view illustrating the solar cell module in the embodiment of the present invention.

FIG. 7 shows a plan view of a conventional solar cell module.

### DESCRIPTION OF EMBODIMENTS

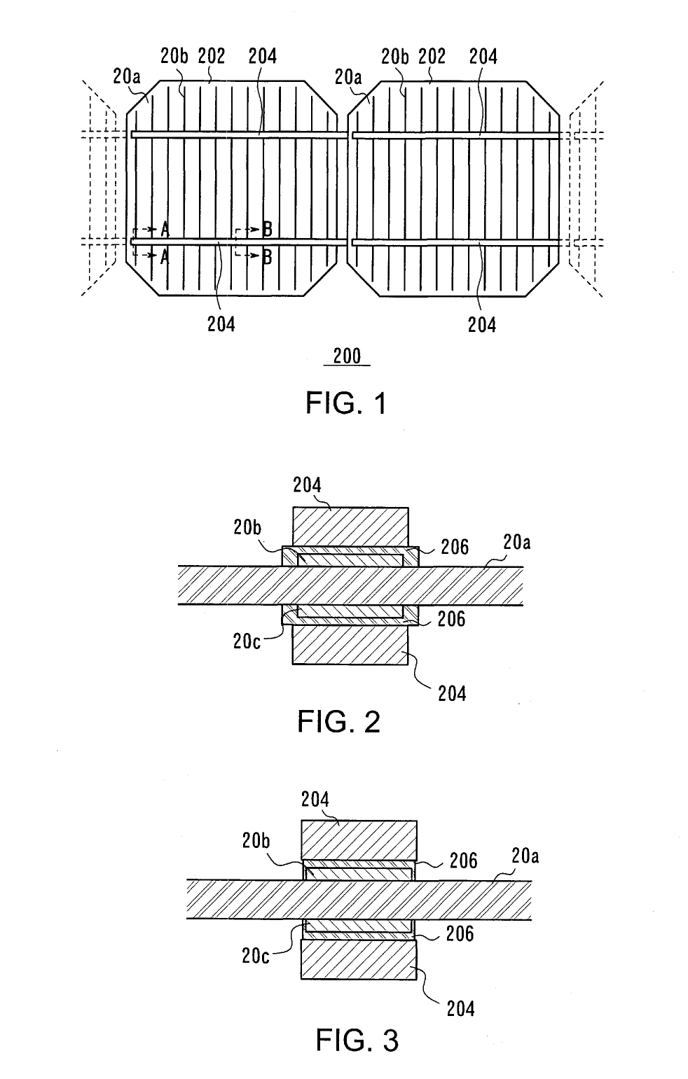

A solar cell module 200 according to an embodiment of the present invention is, as shown in the plan view in FIG. 1 and in the cross-sectional views in FIG. 2 and FIG. 3, configured to include solar cells 202, connecting members 204, and adhesive layers 206. FIG. 1 shows the plan view of the solar cell module 200 as seen from the light receiving surface side. FIG. 2 shows the cross-sectional view, taken along line A-A in FIG. 1, and FIG. 3 shows the cross-sectional view, taken along line B-B in FIG. 1.

The “light receiving surface” is one of the main surfaces of the solar cell 202 and is a surface which receives light mainly entering from outside. For example, 50% to 100% of incident light to the solar cell 202 enters from the light receiving surface side. There is a “back surface” which is one of the main surfaces of the solar cell 202, and is a surface on the opposite side to the light receiving surface.

The solar cell 202 includes a photoelectric conversion unit 20a which generates carriers (electrons and holes) by receiving light such as solar light, a first electrode 20b provided on the light receiving surface of the photoelectric conversion unit 20a, and a second electrode 20c provided on the back surface of the photoelectric conversion unit 20a. The first electrode 20b is, as shown in FIG. 1, a collecting electrode which has fingers arranged in a pectinate shape so as to intersect the extending direction of the connecting member 204, and bus bars for connecting the fingers. The fingers are thin line electrodes for collecting electrical power from the photoelectric conversion unit 20a. The bus bars are electrodes for connecting the plurality of fingers, and are arranged in parallel to each other with a predetermined space therebetween so as to be covered by the connecting members 204. The fingers and the bus bars are formed, for example, by screen printing with a conductive paste. The conductive paste comprises conductive fillers such as silver (Ag) which are dispersed in a binder resin, and is provided in a desired pattern on a transparent conductive layer. The second electrode 20c is provided on the back surface side of the photoelectric conversion unit 20a in the same manner as the first electrode 20b. In the solar cell 202, the carriers generated by the photoelectric conversion unit 20a are collected by the first electrode 20b and the second electrode 20c.

Because, in the solar cell 202, light entering the back surface is less than that entering the light receiving surface, the second electrode 20c on the back surface may have a larger area than the first electrode 20b on the light receiving surface. For example, the second electrode 20c may have a larger number of fingers than the first electrode 20b. Further, if there is no light entering from the back surface side of the solar cell 202, a metal layer made of, for example, silver (Ag) may be formed on approximately the entire surface of the back surface of the photoelectric conversion unit 20a and may be used as the second electrode 20c.

The photoelectric conversion unit 20a has a substrate made of a semiconductor material, such as, for example, crystalline silicon, gallium arsenide (GaAs), or indium phosphide (InP). Although the structure of the photoelectric conversion unit 20a is not particularly limited, in the present embodiment, the description will be provided on the assumption that the structure has a heterojunction between an n-type monocrystal silicon substrate and amorphous silicon. In the photoelectric conversion unit 20a, for example, an i-type amorphous silicon, a p-type amorphous silicon in which, for example, boron (B) is doped, and a transparent conductive layer made of transparent conductive oxide, such as indium oxide, are layered in this order. Further, on the back surface of the substrate, an i-type amorphous silicon layer, an n-type amorphous silicon layer in which, for example, phosphorus (P) is doped, and a transparent conductive layer are layered in this order.

In the solar cell module 200, the adjacent solar cells 202 are connected to each other by the conductive connecting members 204. A metallic foil made of, for example, copper can be used as the connecting member 204. The connecting member 204 connects the first electrode 20b of the solar cell 202 with the second electrode 20c of the adjacent solar cell 202. The connecting members 204 are adhered to the bus bars and the fingers of the first electrode 20b of one solar cell 202 and to the bus bars and the fingers of the second electrode 20c of another solar cell 202, using an adhesive layer 206.

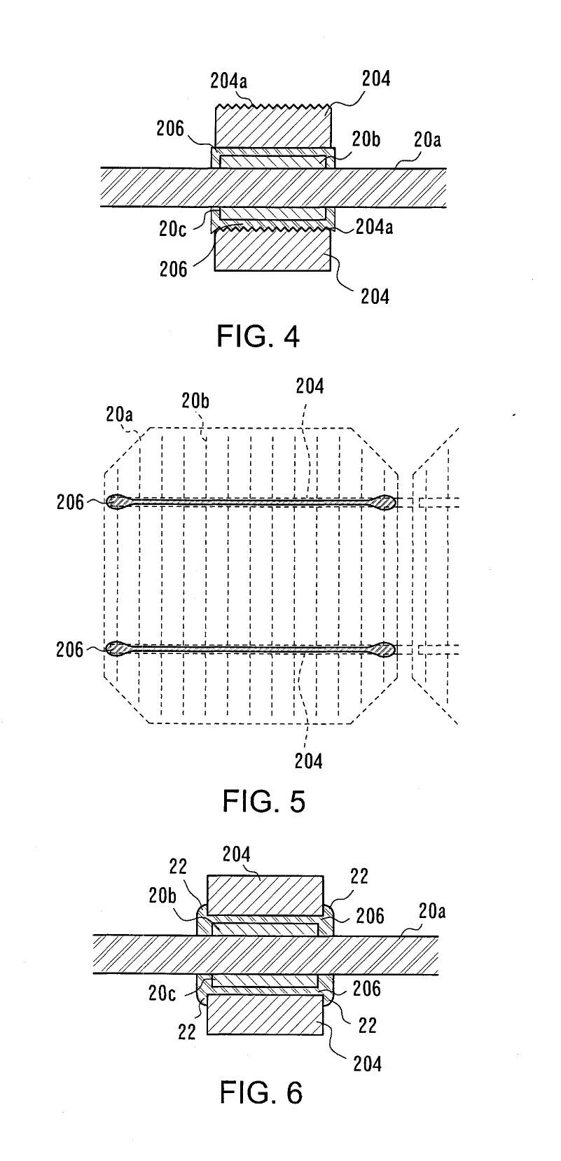

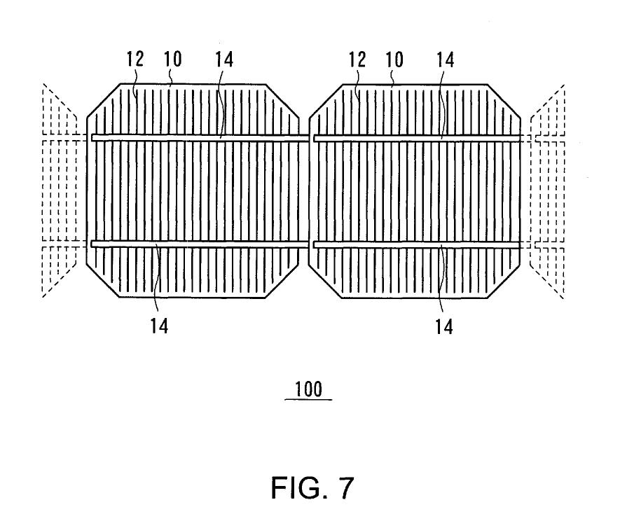

For example, a conductive adhesive film or a conductive adhesive paste in which conductive particles are dispersed in an adhesive thermosetting resin material, such as epoxy resin, acrylic resin, or urethane resin, can be used as the adhesive layer 206. The conductive adhesive film may be an anisotropic conductive adhesive which has high conductivity in the in-plane direction of the solar cell 202 and lower conductivity in the film thickness direction. Further, a nonconductive paste in which no conductive particle is included in an adhesive thermosetting resin material, such as epoxy resin, acrylic resin, or urethane resin, may also be used. In this case, as shown in FIG. 4, one of the first electrode 20b, the second electrode 20c, and the connecting member 204 is provided with uneven shape 204a so that the first electrode 20b and the second electrode 20c are electrically connected to the connecting member 204 via the uneven shape 204a.

The connecting member 204 has a bent portion on which a step of the thickness of the solar cell 202 is provided. The bent portion is provided such that a structural clearance of the thickness of the solar cell 202 is formed, in order to connect the first electrode 20b to the second electrode 20c so as to arrange the adjacent solar cells 202 within the same plane.

The solar cell module 200 may be sealed by a protection component (not shown), in order to protect the light receiving surface and the back surface of the solar cell 202. For example, a component having translucence, such as a glass plate, a resin plate, or a resin film, can be used as the protection component. Preferably, the protection component provided on the light receiving surface side of the solar cell 202 is a transparent component which transmits light of a wavelength bandwidth used for photoelectric conversion in the solar cell 202. If there is no incident light from the back surface side of the solar cell 202, an opaque plate body or film may be used as the protection component on the back surface side. In this case, a laminated film, such as a resin film having, for example, aluminum foil therein, can be used as the protection component. The protection component is adhered to each of the light receiving surface and the back surface of the solar cell 202 by means of fillers.

In the solar cell module 200 of the present embodiment, the contact lengths between the adhesive layer 206 and the connecting member 204 differ between the edge portion and the central portion of the solar cell 202 along the longitudinal direction of the connecting member 204. More specifically, as shown in FIG. 2 and FIG. 3, the solar cell module 200 has an adhesion portion which has a longer contact length between the adhesive layer 206 and the connecting member 204 at the edge portion of the solar cell 202 than at the central portion along the longitudinal direction of the connecting member 204.

Here, the contact length between the adhesive layer 206 and the connecting member 204 means, as shown in FIG. 2 and FIG. 3, a length over which the adhesive layer 206 and the connecting member 204 contact each other in a cross section which is vertical to the longitudinal direction of the connecting member 204. In addition, the edge portion and the central portion of the solar cell 202 indicate a relative positional relation between them, and the edge portion means an area that is closer to an edge of the solar cell 202 than is the central portion. More specifically, in the present embodiment, when a certain region of the connecting member 204 is focused on, the contact length between the connecting member 204 and the adhesive layer 206 in a region which is closer to the edge of the solar cell 202 than the focused region, is longer than that of the focused region.

For example, as shown in FIG. 5, the adhesive layer 206 may be applied along the longitudinal direction of the connecting member 204 (shown by the dotted line) so that the width of the adhesive layer 206 becomes larger at the edge portion and smaller at the central portion of the solar cell 202. At this time, it is preferable to provide the adhesion portion having the longer contact length between the adhesive layer 206 and the connecting member 204 than at the central portion of the solar cell 202, not only at the edge portion of the connecting member 204 but also at the edge portion of the solar cell 202 on the side from which the connecting member 204 is pulled out toward the adjacent solar cell 202.

To change the contact length between the connecting member 204 and the adhesive layer 206 along the longitudinal direction of the connecting member 204, the application quantity of the adhesive, which becomes the adhesive layer 206 along the longitudinal direction of the connecting member 204, may be changed upon application of the adhesive, which becomes the adhesive layer 206. For example, a larger amount of the adhesive may be applied to the edge portion of the solar cell 202 than at the central portion along the longitudinal direction of the connecting member 204, and then, the connecting member 204 may be crimped. Methods that can be used to change the application amount of the adhesive include changing the moving velocity of a dispenser along the longitudinal direction of the connecting member 204, and changing the ejection pressure of the adhesive from the dispenser along the longitudinal direction of the connecting member 204.

Because, in general, a region which is close to the edge of the solar cell 202 is a region at which adhesion between the connecting member 204 and the first electrode 20b tends to separate, by making the contact length at the edge portion of the solar cell 202 longer than that at the central portion, it is possible to effectively suppress peeling off. In addition, the same can be said about the relationship between the connecting member 204 and the second electrode 20c. Meanwhile, because the contact length is shorter at the central portion than at the edge portion, it is possible to suppress, at the central portion, protrusion of the adhesive layer 206 from the connecting member 204, and control shading loss caused by the adhesive layer 206.

Preferably, as shown in the cross-sectional view in FIG. 6, a fillet 22 of the adhesive layer 206 is formed at the contact portion between the connecting member 204 and the first electrode 20b at the edge of the solar cell 202. The fillet 22 means a portion at which a portion of the adhesive layer 206 contacts the side surface of the connecting member 204. By providing the fillet 22, the contact between the connecting member 204 and the first electrode 20b is strengthened at the edge portion of the solar cell 202, and the effect of suppressing peeling off of the connecting member 204 becomes remarkable. The same can be said about the relationship between the connecting member 204 and the second electrode 20c.

### REFERENCE SIGNS LIST

10 SOLAR CELL, 10 COLLECTING ELECTRODE, 14 CONNECTING MEMBER, 20a PHOTOELECTRIC CONVERSION UNIT, 20b FIRST ELECTRODE, 20c SECOND ELECTRODE, 22 FILLET, 100, 200 SOLAR CELL MODULE, 202 SOLAR CELL, 204 CONNECTING MEMBER, 206 ADHESIVE LAYER.

1. A solar cell module comprising:
a plurality of solar cells; and
a connecting member which connects between the plurality of solar cells via an adhesive layer, and wherein
the solar cell module has an adhesion portion having a contact length between the adhesive layer and the connecting member, the contact length being longer at an edge portion than at a central portion of the solar cell along the longitudinal direction of the connecting member.

2. The solar cell module according to claim 1, wherein the solar cell module has a fillet at the adhesion portion, a side surface of the connecting member and the adhesive layer contacting with each other at the fillet.

3. The solar cell module according to claim 1, wherein the solar cell module has an adhesion portion having a contact length between the adhesive layer and the connecting member, the contact length being longer at the edge portion of the solar cell on the side from which the connecting member is pulled out in the solar cell than at the central portion of the solar cell.

4. The solar cell module according to claim 2, wherein the solar cell module has an adhesion portion having a contact length between the adhesive layer and the connecting member, the contact length being longer at the edge portion of the solar cell on the side from which the connecting member is pulled out in the solar cell than at the central portion of the solar cell.
